(19) United States
(12) Patent Application Publication
(10) Pub. No.: US 2026/0182167 A1
(43) Pub. Date: Jun. 25, 2026

(54) DISPLAY DEVICE

(71) Applicant: LG Display Co., Ltd., Seoul (KR)

(72) Inventors: DONGIL CHU, Gimpo-si (KR); JUYOUNG PARK, Cheonan-si (KR); MINJOO KIM, Seoul (KR); SUKHYUN KANG, Goyang-si (KR)

(73) Assignee: LG Display Co., Ltd., Seoul (KR)

(21) Appl. No.: 19/403,688

(22) Filed: Nov. 28, 2025

(30) Foreign Application Priority Data
Dec. 24, 2024 (KR) 10-2024-0195984

(51) Int. Cl. H10K 59/124; H10K 50/15; H10K 50/16; H10K 59/122; H10K 59/131; H10K 102/00

(52) U.S. Cl. CPC H10K 59/124; H10K 50/156; H10K 50/166; H10K 59/122; H10K 59/131; H10K 2102/351

(57) ABSTRACT

A display device can include a substrate, a planarization layer disposed on the substrate, a plurality of first electrodes disposed on the planarization layer, a plurality of auxiliary electrodes disposed on the planarization layer so as to be spaced apart from the plurality of first electrodes, an organic layer on the plurality of first electrodes and the plurality of auxiliary electrodes, and a second electrode disposed on the organic layer. A part of an upper surface and a side surface of the plurality of auxiliary electrodes are in contact with the organic layer. Accordingly, leakage current between a plurality of adjacent sub-pixels can be reduced or minimized by the plurality of auxiliary electrode.

### CROSS-REFERENCE TO RELATED APPLICATIONS

This application claims priority to Korean Patent Application No. 10-2024-0195984, filed on Dec. 24, 2024, in the Korean Intellectual Property Office, the disclosure of which is hereby expressly incorporated by reference into the present application.

### BACKGROUND

### Field

The present disclosure relates to a display device, and more particularly, to a display device capable of improving efficiency and power consumption.

### Discussion of the Related Art

As the world enters the information age, the field of display devices that visually display electrical information signals is rapidly developing, and research is being conducted to develop performances such as thinning, weight reduction, and low power consumption for various display devices.

Representative display devices include a liquid crystal display (LCD), a field emission display (FED), an electro-wetting display (EWD), and an organic light emitting display (OLED).

An electroluminescent display device represented by an organic light emitting display device is a self-emitting display device and does not require a separate light source unlike a liquid crystal display device. Therefore, the electroluminescent display device can be manufactured to have a light weight and a small thickness. In addition, the electroluminescent display device is advantageous in terms of power consumption because the electroluminescent display device operates at a low voltage. Further, the electroluminescent display device is expected to be utilized in various fields because the electroluminescent display device is excellent in implementation of colors, response speeds, viewing angles, and contrast ratios (CRs).

### SUMMARY OF THE DISCLOSURE

An object to be achieved by an embodiment of the present disclosure is to provide a display device capable of improving power consumption and efficiency.

An object to be achieved by another embodiment of the present disclosure is to provide a display device capable of reducing a leakage current between a plurality of adjacent sub-pixels.

Objects of the present disclosure are not limited to the above-mentioned objects, and other objects, which are not mentioned above, can be clearly understood by those skilled in the art from the following descriptions.

According to an aspect of the present disclosure, a display device includes a substrate, a planarization layer disposed on the substrate, a plurality of first electrodes disposed on the planarization layer, a plurality of auxiliary electrodes disposed on the planarization layer so as to be spaced apart from the plurality of first electrodes, an organic layer on the plurality of first electrodes and the plurality of auxiliary electrodes, and a second electrode disposed on the organic layer. A part of an upper surface and a side surface of the plurality of auxiliary electrodes are in contact with the organic layer.

A display device according to another example embodiment of the present disclosure includes a substrate on which a plurality of sub-pixels is defined; a plurality of transistors disposed on the substrate; a plurality of power lines disposed on the substrate; a planarization layer disposed on the plurality of transistors and the plurality of power lines; a plurality of first electrodes disposed in each of the plurality of sub-pixels on the planarization layer and electrically connected to the plurality of transistors; a plurality of auxiliary electrodes disposed between the plurality of first electrodes on the planarization layer and electrically connected to the plurality of power lines; an organic layer disposed on the plurality of first electrodes and the plurality of auxiliary electrodes; and a second electrode disposed on the organic layer, a part of an upper surface and a side surface of the plurality of auxiliary electrodes in contact with the organic layer.

Other detailed matters of the embodiments of the present disclosure are included in the detailed description and the drawings.

In the display device according to the example embodiment of the present disclosure, an organic layer having a multi-light emitting unit structure including a plurality of organic light emitting layers is included to achieve high efficiency and low power consumption of the display device.

In the display device according to the example embodiment of the present disclosure, a leakage current flowing between a plurality of adjacent sub pixels is induced to a plurality of auxiliary electrodes and a low potential power line electrically connected to the plurality of auxiliary electrodes to suppress a leakage current problem between a plurality of adjacent sub pixels.

In the display device according to another example embodiment of the present disclosure, a plurality of auxiliary electrodes is formed in multiple layers, and holes are formed in at least some of the plurality of auxiliary electrodes to improve the contact resistance as the contact area of the organic layer electrically connecting the plurality of auxiliary electrodes and the charge generation layer having high conductivity increases.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a block diagram illustrating a display device according to an example embodiment of the present disclosure.

FIG. 2 is an enlarged plan view of area A of FIG. 1.

FIG. 3 is a schematic cross-sectional view of a sub pixel of a display device according to an example embodiment of the present disclosure.

FIG. 4 is a cross-sectional view taken along the line IV-IV′ of FIG. 2.

FIG. 5 is an enlarged plan view of area B of FIG. 4.

FIG. 6 is a schematic cross-sectional view of a sub pixel of a display device according to an example embodiment of the present disclosure.

FIG. 7 is a circuit diagram of a sub pixel of a display device according to an example embodiment of the present disclosure.

FIG. 8 is a schematic cross-sectional view of a display device according to another embodiment of the present disclosure.

FIG. 9 is a schematic cross-sectional view of a display device according to still another example embodiment of the present disclosure.

FIG. 10 is a schematic cross-sectional view of a display device according to still another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Further, in the following description of the present disclosure, a detailed explanation of known related technologies can be omitted to avoid unnecessarily obscuring the subject matter of the present disclosure. The terms such as “including,” “having,” and “comprising” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed therebetween, or it can be disposed directly on the another element or layer.

Although the terms such as “first”, “second”, and the like are used for describing various components, these components are not confined by these terms. These terms are merely used for distinguishing one component from the other components. Therefore, a first component to be mentioned below can be a second component in a technical concept of the present disclosure. Further, the term “can” fully encompasses all the meanings and coverages of the term “may” and vice versa.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, example embodiments of the present disclosure will be described in detail with reference to accompanying drawings. All the components of each display device/apparatus according to all embodiments of the present disclosure are operatively coupled and configured.

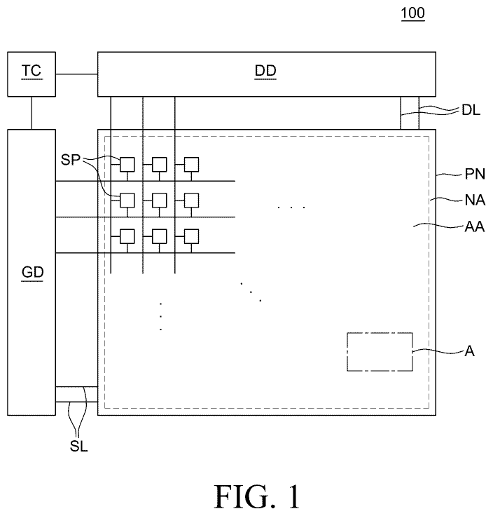

FIG. 1 is a block diagram illustrating a display device according to an example embodiment of the present disclosure. For example, FIG. 1 is a schematic block diagram of a display device according to an example embodiment of the present disclosure. In FIG. 1, for the convenience of description, among various components of the display device 100, only a display panel PN, a gate driver GD, a data driver DD, and a timing controller TC are illustrated.

Referring to FIG. 1, a display device 100 includes a display panel PN including a plurality of sub pixels SP, and a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals provided from the timing controller TC. FIG. 1 illustrates that one gate driver GD is disposed to be spaced apart from one side of the display panel PN. However, the number and arrangement of the gate drivers GD are not limited thereto.

The data driver DD supplies a data voltage to a plurality of data lines DL according to a plurality of data control signals and image data provided from the timing controller TC. The data driver DD can convert image data into a data voltage using a reference gamma voltage and supply the converted data voltage to a plurality of data lines DL.

The timing controller TC aligns image data input from the outside and supplies the image data to the data driver DD. The timing controller TC can generate a gate control signal and a data control signal by using a synchronization signal input from the outside, for example, a dot clock signal, a data enable signal, and a horizontal/vertical synchronization signal. Further, the timing controller TC supplies the generated gate control signal and data control signal to the gate driver GD and the data driver DD, respectively, to control the gate driver GD and the data driver DD.

The display panel PN is configured to display images to a user and includes a plurality of sub-pixels SP. In the display panel PN, the plurality of scan lines SL and the plurality of data lines DL can cross each other, and the plurality of sub pixels SP can be formed at intersections of the scan line SL and the data line DL.

In the display panel PN, an active area AA and a non-active area NA can be defined.

The active area AA is an area in which images are displayed in the display device 100. In the active area AA, a plurality of sub pixels SP constituting a plurality of pixels and a pixel circuit for driving the plurality of sub pixels SP can be disposed. The plurality of sub-pixels SP is a minimum unit constituting the active area AA, and n sub-pixels SP can form one pixel. In each of the plurality of sub pixels SP, a thin film transistor for driving a plurality of light emitting elements can be disposed. The plurality of light emitting elements can be differently defined depending on the type of the display panel PN. For example, when the display panel PN is an organic light emitting display panel, the light emitting element can be an organic light emitting element.

In the active area AA, a plurality of signal lines for transmitting various signals to the plurality of sub-pixels SP is disposed. For example, the plurality of signal lines can include a plurality of data lines DL which supplies a data voltage to each of the plurality of sub pixels SP, a plurality of scan lines SL which supplies a scan signal to each of the plurality of sub pixels SP, and the like. The plurality of scan lines SL can extend in one direction in the active area AA and be connected to the plurality of sub pixels SP, and the plurality of data lines DL can extend in a direction different from the one direction in the active area AA and be connected to the plurality of sub pixels SP. In addition, in the active area AA, a low potential power line, a high potential power line, and the like can be further disposed, but are not limited thereto.

The non-active area NA is an area where an image is not displayed and can be defined as an area extending from the active area AA. In the non-active area NA, a link line and a pad electrode for transmitting a signal to the sub pixel SP of the active area AA, or a driving IC, such as a gate driver IC or a data driver IC, can be disposed.

Meanwhile, a driver such as a gate driver GD, a data driver DD, and a timing controller TC can be connected to the display panel PN in various ways. For example, the gate driver GD can be mounted in the non-active area NA in a gate-in-panel (GIP) manner or mounted between the plurality of sub pixels SP in the active area AA in a gate-in-active area (GIA) manner.

For example, the data driver DD and the timing controller TC are formed on separate flexible film and printed circuit board, and the display panel PN, the data driver DD, and the timing controller TC can be electrically connected by bonding the flexible film and the printed circuit board to the pad electrode formed in the non-active area NA of the display panel PN.

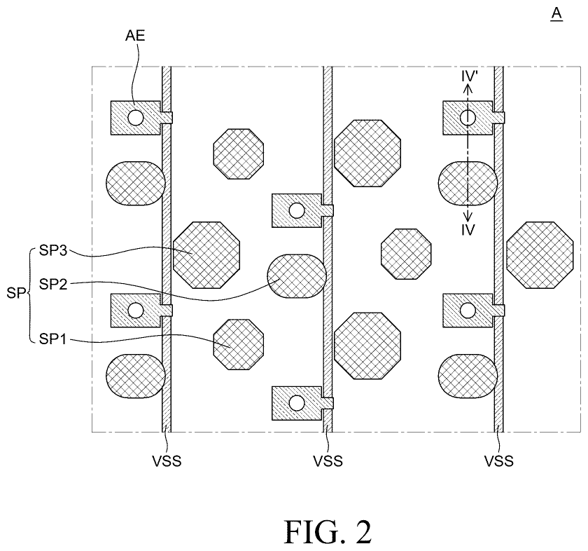

FIG. 2 is an enlarged plan view of area A of FIG. 1. Particularly, FIG. 2 is an enlarged view of area A which is a part of the active area AA of the display panel PN of FIG. 1 and illustrates a planar shape of a plurality of sub pixels SP disposed in the active area AA. In FIG. 2, for the convenience of description, only a plurality of first sub pixels SP1, a plurality of second sub pixels SP2, a plurality of third sub pixels SP3, a plurality of auxiliary electrodes AE, and a plurality of low potential power lines VSS are illustrated.

In the active area AA, a plurality of sub-pixels SP constituting a plurality of pixels PX can be disposed. For example, one pixel PX can include a plurality of sub pixels SP which emits light with different wavelengths. For example, one pixel PX can include a first sub-pixel SP1, a second sub-pixel SP2, and a third sub-pixel SP3. However, the present disclosure is not limited thereto, and one pixel PX can further include a fourth sub-pixel (SP4). For example, the first sub-pixel SP1 can emit red light, the second sub-pixel SP2 can emit green light, and the third sub-pixel SP3 can emit blue light. For example, when the pixel PX further includes the fourth sub-pixel (SP4), the fourth sub-pixel (SP4) can emit white light.

In the active area AA, a plurality of auxiliary electrodes AE can be disposed in a plurality of pixels PX. For example, at least one auxiliary electrode AE can be included per pixel PX. However, the present disclosure is not limited thereto and at least one auxiliary electrode AE can be included in each of the plurality of sub-pixels SP as necessary.

The plurality of auxiliary electrodes AE can be disposed to be spaced apart from the plurality of sub-pixels SP, specifically, the first electrodes of the plurality of sub-pixels SP.

In the active area AA, the plurality of auxiliary electrodes AE can be electrically connected to the plurality of low potential power lines VSS.

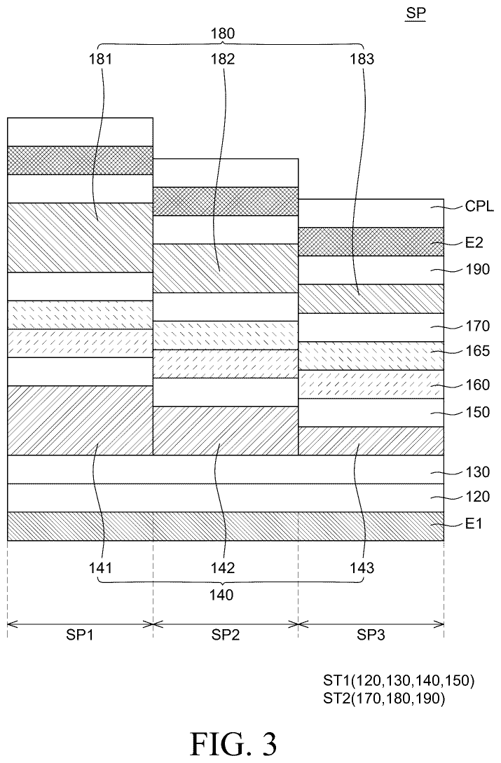

FIG. 3 is a schematic cross-sectional view of a sub pixel of a display device according to an example embodiment of the present disclosure.

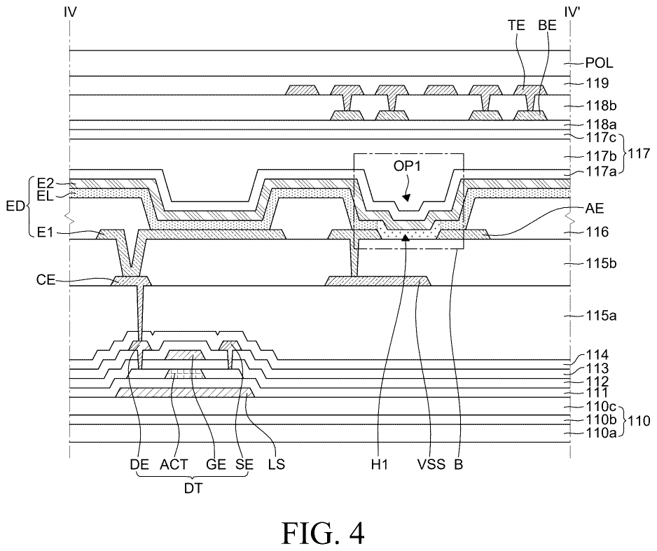

Referring to FIG. 3, the light emitting element ED (see FIG. 4) of the display device 100 according to the embodiment of the present disclosure can include a first electrode E1, a hole injection layer 120, a first hole transport layer 130, a first organic light emitting layer 140 which is formed of the 1-1 light emitting layer 141, the 1-2 light emitting layer 142 and the 1-3 light emitting layer 143, a first electron transport layer 150, a first charge generation layer 160, a second charge generation layer 165, a second hole transport layer 170, a second organic light emitting layer 180 which is formed of a 2-1 light emitting layer 181, a 2-2 light emitting layer 182 and a 2-3 light emitting layer 183, a second electron transport layer 190, a second electrode E2 and a capping layer, in which the first sub pixel SP1, the second sub pixel SP2, and the third sub pixel SP3 are defined.

Further, the light emitting element ED according to the example embodiment of the present disclosure can have a structure in which the first light emitting unit ST1 including the first organic light emitting layer 140 and the second light emitting unit ST2 including the second organic light emitting layer 180 are stacked between the first electrode E1 and the second electrode E2.

The first light-emitting unit ST1 includes a hole injection layer 120, a first hole transport layer 130, a first organic light-emitting layer 140, and a first electron transport layer 150.

Further, the second light emitting unit ST2 includes a second hole transport layer 170, a second organic light emitting layer 180, and a second electron transport layer 190.

Further, the light emitting element ED according to the example embodiment of the present disclosure can include a first charge generation layer 160 which is an n-type charge generation layer positioned between the first light emitting unit ST1 and the second light emitting unit ST2 and a second charge generation layer 165 which is a p-type charge generation layer.

The first electrode E1 is positioned in each of the first sub-pixel SP1, the second sub-pixel SP2, and the third sub-pixel SP3 and can include a transparent conductive layer and a reflective layer. For example, the display device can include a transparent conductive material layer having a high work function, such as indium-tin-oxide (ITO), and a reflective layer, such as silver (Ag) or silver alloy (Ag alloy).

The hole injection layer 120 is positioned on the first electrode E1 so as to correspond to all the first sub-pixel SP1, the second sub-pixel SP2, and the third sub-pixel SP3.

The hole injection layer 120 can serve to facilitate the injection of holes, and can be made of any one or more selected from the group consisting of HATCN (1,4,5,8,9,11-hexaazatriphenylene-hexantirile) and CuPc (cupper phthalocyanine), PEDOT (poly(3,4)-ethylenedioxythiophene), PANI (polyaniline), and NPD (N, N-dinaphthyl-N, N′-diphenylbenzidine), but is not limited thereto.

The first hole transport layer 130 and the second hole transport layer 170 are disposed to correspond to the first sub-pixel SP1, the second sub-pixel SP2, and the third sub-pixel SP3, respectively. The first hole transport layer 130 is positioned on the hole injection layer 120, and the second hole transport layer 170 is positioned on the second charge generation layer 165.

The first hole transport layer 130 and the second hole transport layer 170 serve to facilitate the transport of holes and can be formed of any one or more selected from the group consisting of NPD (N, N-dinaphthyl-N, N′-diphenylbenzidine, TPD (N, N′-bis-(3-methylphenyl)-N, N′-bis-(phenyl)-benzidine), s-TAD and MTDATA (4,4′,4-Tris(N-3-methylphenyl-N-phenyl-amino)-triphenylamine), but are not limited thereto.

The 1-1 light emitting layer 141 and the 2-1 light emitting layer 181, the 1-2 light emitting layer 142 and the 2-2 light emitting layer 182, and the 1-3 light emitting layer 143 and the 2-3 light emitting layer 183 are positioned in the first sub pixel SP1, the second sub pixel SP2, and the third sub pixel SP3, respectively.

Each of the 1-1 light emitting layer 141 and the 2-1 light emitting layer 181 can include a light emitting material that emits red light, and the light emitting material can include a phosphorescent material or a fluorescent material. For example, the 1-1 light emitting layer 141 and the 2-1 light emitting layer 181 each include a host material including CBP(carbazole biphenyl) or mCP (1,3-bis(carbazole-9-yl)). The 1-1 light emitting layer 141 and the 2-1 light emitting layer 181 can be made of phosphorescent material include a dopant selected from the group including PIQIr(acac)(bis(1-phenylisoquinolin) acetylacetonate iridium), PQIr(acac)(bis(1-phenylquinolin) acetylacetonate iridium), PQIr(tris(1-phenylquinoline)iridium), and PtOEP(octaethylporphyrin platinum). Alternatively, the 1-1 light emitting layer 141 and the 2-1 light emitting layer 181 can be made of fluorescent material include PBD:Eu(DBM)3(Phen) or Perylene. However, the present disclosure is not limited thereto.

Each of the 1-2 light emitting layer 142 and the 2-2 light emitting layer 182 can include a light emitting material that emits green light, and the light emitting material can include a phosphorescent material or a fluorescent material. For example, the 1-2 light emitting layer 142 and the 2-2 light emitting layer 182 each include a host material including CBP or mCP, and can be formed of a phosphorescent material including a dopant material such as an Ir complex including Ir(ppy)3(fac tris(2-phenylpyridine)iridium), or on the contrary, can be formed of a fluorescent material including Alq3(tris(8-hydroxyquinolino)aluminum), but is not limited thereto.

Further, each of the 1-3 light emitting layer 143 and the 2-3 light emitting layer 183 can include a light emitting material that emits blue light, and the light emitting material can include a phosphorescent material or a fluorescent material. For example, each of the 1-3 light emitting layer 143 and the 2-3 light emitting layer 183 includes a host material including CBP or mCP, and can be made of a phosphorescent material including a dopant material including (4,6-F2ppy)2Ir(pic). In addition, it can be made of a fluorescent material including any one selected from the group consisting of spiro-DPVBi, spiro-6P, distyrylbenzene (DSB), distyrylarylene (DSA), PFO-based polymer, and PPV-based polymer, but is not limited thereto.

At this time, in order to match an optical distance required for light emission of each of the first light emitting unit ST1 and the second light emitting unit ST2 of the first sub pixel SP1, the second sub pixel SP2, and the third sub pixel SP3, a thickness or height of each of the 1-1 light emitting layer 141, the 1-2 light emitting layer 142, and the 1-3 light emitting layer 143 included in the first organic light emitting layer 140 can be different from a thickness or height of each of the 2-1 light emitting layer 181, the 2-2 light emitting layer 182, and the 2-3 light emitting layer 183 included in the second organic light emitting layer 180.

The first electron transport layer 150 is positioned on the first organic light emitting layer 140 and the second electron transport layer 190 is positioned on the second organic light emitting layer 180.

The first electron transport layer 150 and the second electron transport layer 190 can serve to transport and inject electrons, and thicknesses of the first electron transport layer 150 and the second electron transport layer 190 can be adjusted in consideration of electron transport characteristics. In addition, if necessary, an electron injection layer can be selectively further included on the second electron transport layer 190.

The first electron transport layer 150 and the second electron transport layer 190 serve to facilitate the transport of electrons and can be formed of any one or more selected from the group consisting of Alq3(tris (8-hydroxyquinolino)aluminum), PBD(2-(4-biphenylyl)-5-(4-tert-butylpheny)-1,3,4oxadiazole), TAZ, spiro-PBD, BAlq, and SAlq, but are not limited thereto.

The first charge generation layer 160 is positioned on the first electron transport layer 150, and the second charge generation layer 165 is positioned on the first charge generation layer 160. Further, the first charge generation layer 160 and the second charge generation layer 165 are positioned between the first light emitting unit ST1 and the second light emitting unit ST2. The first charge generation layer 160 and the second charge generation layer 165 serve to adjust a charge balance between the first light emitting unit ST1 and the second light emitting unit ST2.

The first charge generation layer 160 serves as an n-type charge generation layer (n-CGL) that assists in injecting electrons into the first light emitting unit ST1, and the second charge generation layer 165 serves as a p-type charge generation layer (p-CGL) that assists in injecting holes into the second light emitting unit ST2.

More specifically, the first charge generation layer 160, which is an n-type charge generation layer (n-CGL) serving as electron injection, can be formed of an alkali metal, an alkali metal compound, an organic material serving as electron injection, or a compound thereof.

Further, the host material of the first charge generation layer 160 can be formed of the same material as the first electron transport layer 150 or the second electron transport layer 190. For example, the n-type organic material, such as an anthracene derivative, can be formed of a mixed layer doped with a dopant such as lithium (Li), but is not limited thereto.

The second charge generation layer 165 is positioned on the first charge generation layer 160. The second charge generation layer 165 serves as a p-type charge generation layer (p-CGL) serving as hole injection and can be formed of the same material as the first hole transport layer 130 or the second hole transport layer 170. For example, it can be formed of a single layer of a p-type material such as HATCN and F4-TCNQ, but is not limited thereto.

The second electrode E2 is positioned on the second electron transport layer 190. For example, the second electrode E2 can be formed of indium tin oxide (ITO), indium zinc oxide (IZO), indium tin zinc oxide (ITZO), zinc oxide (ZnO), and tin oxide (TO)-based transparent conductive oxide, or an ytterbium (Yb) alloy. For example, the second electrode E2 can be made of an alloy (Mg:Ag) of magnesium and silver to have semi-transmissive properties. For example, light emitted from the first organic light emitting layer 140 and the second organic light emitting layer 180 is displayed to the outside through the second electrode E2, and since the second electrode E2 has a transflective characteristic, some of the light is directed back to the first electrode E1.

As described above, light is repeatedly reflected in the cavity between the first electrode E1 and the second electrode E2 due to a micro-cavity effect in which repeated reflection occurs between the first electrode E1 and the second electrode E2 serving as a reflective layer, thereby increasing light efficiency.

In addition, the first electrode E1 is formed as a transmissive electrode, and the second electrode E2 is formed as a reflective electrode, so that light from the organic light emitting layer can be displayed to the outside through the first electrode E1.

The capping layer CPL is positioned on the second electrode E2. The capping layer CPL is provided to increase a light extraction effect of the light emitting element ED and can be formed of the same material as the first hole transport layer 130, the second hole transport layer 170, the first electron transport layer 150, the second electron transport layer 190, the first organic light emitting layer 140, or the second organic light emitting layer 180. Further, the capping layer CPL can be selectively omitted as necessary.

FIG. 4 is a cross-sectional view taken along the line IV-IV′ of FIG. 2. In FIG. 4, for the convenience of description, components included in one sub pixel SP and one auxiliary electrode AE disposed in the active area AA are shown.

Referring to FIG. 4, the substrate 110 is a component for supporting various components included in the display device 100 and can be formed of an insulating material. The substrate 110 can include a first substrate 110a, an insulating layer 110b, and a second substrate 110c. The insulating layer 110b can be disposed between the first substrate 110a and the second substrate 110c. As described above, the substrate 110 is configured by the first substrate 110a, the second substrate 110c, and the insulating layer 110b to suppress moisture permeation. For example, the first substrate 110a and the second substrate 110c can be polyimide (PI) substrates.

The light shielding layer LS is disposed in each of the plurality of sub-pixels on the substrate 110. The light shielding layer LS blocks light incident onto an active layer ACT of the driving transistor DT to be described below from a lower portion of the substrate 110. Light which is incident onto the active layer ACT of the driving transistor DT is blocked by the light shielding layer LS to minimize a leakage current.

A buffer layer 111 is disposed on the substrate 110 and the light shielding layer LS. The buffer layer 111 can reduce penetration of moisture or impurities through the substrate 110. For example, the buffer layer 111 can be configured as a single layer or multilayer made of silicon oxide (SiOx) or silicon nitride (SiNx), but is not limited thereto. However, the buffer layer 111 can be omitted depending on the type of substrate 110 or the type of transistor, but is not limited thereto.

The driving transistor DT of each of the plurality of sub pixels SP is disposed on the buffer layer 111. The driving transistor DT is a transistor for controlling a driving current supplied to the light emitting element ED.

The driving transistor DT includes an active layer ACT, a gate electrode GE, a source electrode SE, and a drain electrode DE.

The active layer ACT of the driving transistor DT can be disposed on the buffer layer 111. For example, the active layer ACT can be formed of polysilicon (p-Si), amorphous silicon (a-Si), or an oxide semiconductor, but is not limited thereto.

The gate insulating layer 112 can be disposed on the active layer ACT. The gate insulating layer 112 is an insulating layer which insulates the active layer ACT from the gate electrode GE and can be formed of silicon oxide (SiOx), silicon nitride (SiNx), or a double layer thereof.

Further, the gate electrode GE of the driving transistor DT can be disposed on the gate insulating layer 112. The gate electrode GE is disposed on the gate insulating layer 112 so as to overlap the active layer ACT. The gate electrode GE can be formed of various conductive materials, such as magnesium (Mg), aluminum (Al), nickel (Ni), chromium (Cr), molybdenum (Mo), tungsten (W), gold (Au), or an alloy thereof, but is not limited thereto.

The interlayer insulating layer 113 can be disposed to cover the gate electrode GE. The interlayer insulating layer 113 is an insulating layer which protects components below the interlayer insulating layer 113 and can be configured by a single layer or a double layer of silicon oxide (SiOx) or silicon nitride (SiNx), but is not limited thereto.

The source electrode SE and the drain electrode DE of the driving transistor DT can be disposed on the interlayer insulating layer 113.

The source electrode SE and the drain electrode DE can be connected to one side and the other side of the active layer ACT, respectively, through contact holes provided in the interlayer insulating layer 113 and the gate insulating layer 112. The source electrode SE and the drain electrode DE can be formed of various conductive materials, such as magnesium (Mg), aluminum (Al), nickel (Ni), chromium (Cr), molybdenum (Mo), tungsten (W), gold (Au), or an alloy thereof, but are not limited thereto.

A portion of the active layer ACT overlapping the gate electrode GE is a channel region. One of the source electrode SE and the drain electrode DE is connected to one side of the channel region in the active layer ACT, and the other is connected to the other side of the channel region in the active layer ACT.

The passivation layer 114 can be disposed on the source electrode SE and the drain electrode DE. The passivation layer 114 is provided to protect the driving transistor DT and can be formed of an inorganic layer, for example, silicon oxide (SiOx), silicon nitride (SiNx), or a double layer thereof.

The first planarization layer 115a can be disposed on the passivation layer 114. The first planarization layer 115a can protect the driving transistor DT and planarize an upper portion thereof. The first planarization layer 115a can be configured by a single layer or a double layer, and for example, can be formed of photoresist or an acrylic organic material, but is not limited thereto.

The connection electrode CE can be disposed on the first planarization layer 115a.

The connection electrode CE can be connected to one of the source electrode SE and the drain electrode DE through a contact hole provided in the first planarization layer 115a.

A plurality of low potential power lines VSS is disposed on the first planarization layer 115a. For example, the plurality of low potential power lines VSS can be formed of an opaque conductive material such as titanium (Ti), gold (Au), silver (Ag), copper (Cu), molybdenum (Mo), aluminum (Al), or an alloy thereof, a conductive material such as indium tin oxide (ITO), or a stacked structure thereof, but is not limited thereto.

The second planarization layer 115b can be disposed on the connection electrode CE and the plurality of low potential power lines VSS. The second planarization layer 115b can be made of the same material as the first planarization layer 115a.

The light emitting element ED can be positioned on the second planarization layer 115b.

Hereinafter, a stack structure of the light emitting element ED will be described in detail.

The first electrode E1 can be disposed on the second planarization layer 115b. In this case, the first electrode E1 can be electrically connected to the connection electrode CE through a contact hole provided in the second planarization layer 115b. The first electrode E1 can be formed of a metallic material.

When the display device 100 is a top emission type in which light emitted from the light emitting element ED is emitted above the substrate 110 on which the light emitting element ED is disposed, the first electrode E1 can include a first transparent conductive layer CL1, a reflective layer RL on the first transparent conductive layer CL1, and a second transparent conductive layer CL2 on the reflective layer RL. The first transparent conductive layer CL1 and the second transparent conductive layer CL2 can be formed of a transparent conductive oxide such as ITO or IZO, and the reflective layer RL can be formed of, for example, silver (Ag), aluminum (Al), gold (Au), molybdenum (Mo), tungsten (W), chromium (Cr), or an alloy thereof.

The auxiliary electrode AE can be disposed on the second planarization layer 115b to be spaced apart from the first electrode E1. A plurality of auxiliary electrodes AE can be disposed between a plurality of first electrodes E1. In this case, the auxiliary electrode AE can be electrically connected to the low potential power line VSS through a contact hole provided in the second planarization layer 115b. The auxiliary electrode AE can be formed of the same material as the first electrode AE.

At least a portion of the auxiliary electrode AE can include a first hole H1 exposing an upper surface of the second planarization layer 115b. The bank 116 can be disposed while covering an end of the first electrode E1 and can define an emission area. A portion of the bank 116 corresponding to the emission area of the sub-pixel SP can be opened. A part of the first electrode E1 can be exposed through the open part of the bank 116 (hereinafter, referred to as an open area). In this case, the bank 116 can be made of an inorganic insulating material, such as silicon nitride (SiNx) or silicon oxide (SiOx), or an organic insulating material, such as benzocyclobutene-based resin, acrylic-based resin, or imide-based resin, but is not limited thereto.

Further, the bank 116 can include a first opening OP1 which overlaps the first hole H1 and exposes a part of the upper surface and a part of the side surface of the auxiliary electrode AE.

The organic layer EL can be disposed on the bank 116. Accordingly, the organic layer EL can be disposed on the first electrode E1 exposed through the open area of the bank 116. The organic layer EL can be disposed on a plurality of auxiliary electrodes AE. Further, the organic layer EL can be disposed on the second planarization layer 115b exposed through the first opening OP1 of the bank 116 and the first hole H1 of the auxiliary electrode AE.

The second electrode E2 can be disposed on the organic layer EL.

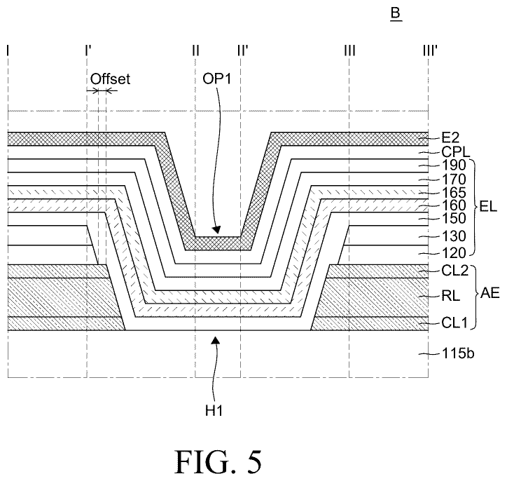

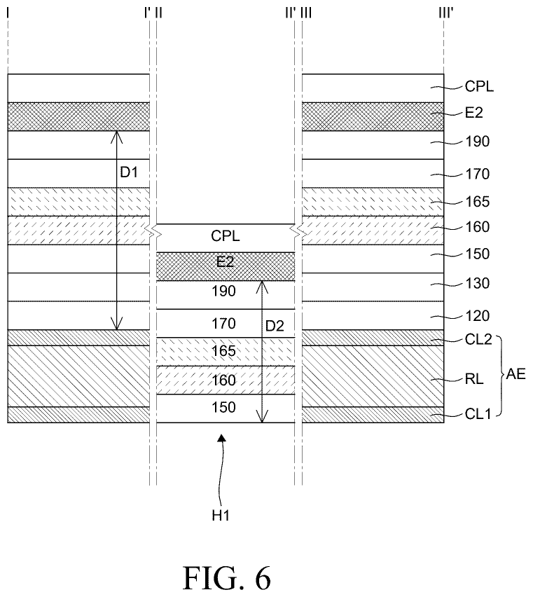

The light emitting element ED can be formed by the first electrode E1, the organic layer EL, and the second electrode E2. The organic layer EL can include a plurality of organic material layers. This will be described in detail with reference to FIGS. 5 and 6 to be described below.

The encapsulation part 117 can be located on the light emitting element ED described above.

The encapsulation part 117 can have a single-layered structure or a multi-layered structure. For example, the encapsulation part 117 can include a first encapsulation layer 117a, a second encapsulation layer 117b, and a third encapsulation layer 117c.

In this case, the first encapsulation layer 117a and the third encapsulation layer 117c can be configured by inorganic layers, and the second encapsulation layer 117b can be configured by an organic layer. Among the first encapsulation layer 117a, the second encapsulation layer 117b, and the third encapsulation layer 117c, the second encapsulation layer 117b is thickest and can serve as a planarization layer.

The first encapsulation layer 117a is disposed on the second electrode E2 and can be disposed to be most adjacent to the light emitting element ED. The first encapsulation layer 117a can be formed of an inorganic insulating material on which low-temperature deposition can be performed. For example, the first encapsulation layer 117a can be made of silicon nitride (SiNx), silicon oxide (SiOx), silicon oxynitride (SiON), or aluminum oxide (Al₂O₃). Since the first encapsulation layer 117a is deposited in a low temperature atmosphere, it is possible to prevent damage to the organic layer EL including an organic material vulnerable to a high temperature atmosphere during the deposition process.

The second encapsulation layer 117b can be formed to have a smaller area than that of the first encapsulation layer 117a. In this case, the second encapsulation layer 117b can be formed to expose both ends of the first encapsulation layer 117a. The second encapsulation layer 117b can serve to alleviate stress between layers and to enhance planarization performance.

For example, the second encapsulation layer 117b can be made of an organic insulating material such as acrylic resin, epoxy resin, polyimide, polyethylene, or silicon oxycarbon (SiOC). For example, the second encapsulation layer 117b can be formed by an inkjet method, but is not limited thereto.

The third encapsulation layer 117c can be formed above the substrate 110 on which the second encapsulation layer 117b is formed so as to cover upper surfaces and side surfaces of the second encapsulation layer 117b and the first encapsulation layer 117a. In this case, the third encapsulation layer 117c can minimize or block the permeation of external moisture or oxygen into the first encapsulation layer 117a and the second encapsulation layer 117b. For example, the third encapsulation layer 117c can be made of an inorganic insulating material such as silicon nitride (SiNx), silicon oxide (SiOx), silicon oxynitride (SiON), or aluminum oxide (Al₂O₃).

A touch sensing unit can be disposed on the encapsulation part 117 described above.

Specifically, the touch sensing unit can include a touch buffer layer 118a disposed on the encapsulation part 117, a bridge electrode BE disposed on the touch buffer layer 118a, a touch interlayer insulating layer 118b disposed on the touch buffer layer 118a and the bridge electrode BE, and a plurality of touch electrodes TE disposed on the touch interlayer insulating layer 118b.

The touch buffer layer 118a can block a chemical solution such as a developer or an etching solution used in the manufacturing process of touch electrodes formed on the touch buffer layer 118a or external moisture or foreign substances from penetrating into the light emitting element.

The plurality of touch electrodes TE can include a plurality of first touch electrodes extending in a first direction and a plurality of second touch electrodes extending in a second direction intersecting the first direction.

For example, the plurality of first touch electrodes and the plurality of second touch electrodes can be disposed on the same layer. However, in an area where the plurality of first touch electrodes and the plurality of second touch electrodes intersect, the plurality of second touch electrodes can be separately disposed, and the plurality of separated second touch electrodes can be connected by the bridge electrode BE. A touch interlayer insulating layer 118b can be disposed between the plurality of second touch electrodes and the bridge electrode BE.

The protective layer 119 can be disposed to cover the touch sensing unit. The protective layer 119 can be formed of an organic insulating layer. The step on the uppermost layer of the display device 100 can be prevented by the protective layer 119, thereby improving the visibility of the display device 100.

The polarization layer POL can be disposed on the protective layer 119. The polarization layer POL is a layer for polarizing incident light and is a film having a predetermined level of light transmittance to absorb external light and reflected light thereof to prevent a decrease in contrast ratio. Specifically, the display panel PN includes various metal materials applied to semiconductor devices, wiring lines, organic light emitting devices, and the like. Therefore, the external light incident onto the display panel PN can be reflected from the metal material, and the visibility of the display device 100 can be reduced due to the reflection of the external light. Therefore, the polarization layer POL is disposed to suppress the reflection of external light, thereby increasing the outdoor visibility of the display device 100.

FIG. 5 is an enlarged plan view of area B of FIG. 4. FIG. 6 is a schematic cross-sectional view of a sub pixel of a display device according to an example embodiment of the present disclosure. In FIGS. 5 and 6, for the convenience of description, components above the organic layer EL and the organic layer EL are shown in an area overlapping the auxiliary electrode AE.

Referring to FIGS. 5 and 6, the organic layer EL overlapping the auxiliary electrode AE can include a hole injection layer 120, a first hole transport layer 130, a first electron transport layer 150, a first charge generation layer 160, a second charge generation layer 165, a second hole transport layer 170, and a second electron transport layer 190.

In this case, a first hole H1 exposing the upper surface of the second planarization layer 115b can be included in at least a part of the auxiliary electrode AE.

The first hole H1 can be formed by irradiating at least a part of the auxiliary electrode AE with laser beams after the auxiliary electrode AE is formed. For example, the auxiliary electrode AE is formed on the second planarization layer 115b, and then the hole injection layer 120 and the first hole transport layer 130 are formed. Next, a first hole H1 is formed in the auxiliary electrode AE, the hole injection layer 120, and the first hole transport layer 130 using a laser. Next, the first electron transport layer 150, the first charge generation layer 160, the second charge generation layer 165, the second hole transport layer 170, and the second electron transport layer 190 can be formed.

As the first hole H1 is formed in at least a part of the auxiliary electrode AE using a laser, the side surface of the auxiliary electrode AE can have a gentle taper shape. In addition, an offset can be formed between the auxiliary electrode AE and the hole injection layer 120 and the first hole transport layer 130 disposed above the auxiliary electrode AE by forming the first hole H1 in at least a portion of the auxiliary electrode AE using a laser.

In the first hole H1 or on an upper surface of the second planarization layer 115b in the first hole H1, only the first electron transport layer 150, the first charge generation layer 160, the second charge generation layer 165, the second hole transport layer 170, and the second electron transport layer 190 among the organic layer EL can be disposed.

Referring to FIG. 6, the thickness D1 of the organic layer EL disposed on the upper surface of the auxiliary electrode AE can be greater than the thickness D2 of the organic layer EL disposed in the first hole H1.

In the first hole H1, the plurality of auxiliary electrodes AE can be in contact with the first electron transport layer 150 and can be electrically connected to the first charge generation layer 160 and the second charge generation layer 165 through the first electron transport layer 150. Accordingly, the auxiliary electrode AE can be electrically connected to the first charge generation layer 160 and the second charge generation layer 165 having high conductivity. Further, the low potential power line VSS electrically connected to the auxiliary electrode AE can also be electrically connected to the first charge generation layer 160 and the second charge generation layer 165.

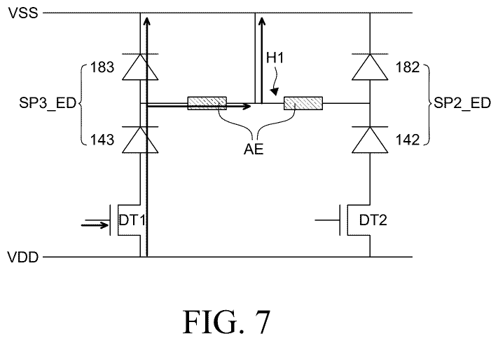

FIG. 7 is a circuit diagram of a sub pixel of a display device according to an example embodiment of the present disclosure. Particularly, FIG. 7 is a circuit diagram illustrating a current path between a second sub-pixel SP2 and a third sub-pixel SP3 adjacent to each other among the plurality of sub-pixels SP.

Specifically, referring to FIG. 7, the light emitting element SP2_ED of the second sub-pixel can have a structure in which a first light emitting unit including the 1-2 light emitting layer 142 and a second light emitting unit including the 2-2 light emitting layer 182 are stacked.

The light emitting element SP3_ED of the third sub-pixel can have a structure in which a first light emitting unit including the 1-3 light emitting layer 143 and a second light emitting unit including the 2-3 light emitting layer 183 are stacked.

For example, the first driving transistor DT1 can be electrically connected to the light emitting element SP3_ED of the third sub pixel, and the second driving transistor DT2 can be electrically connected to the light emitting element SP2_ED of the second sub pixel.

In this case, the first driving transistor DT1 and the second driving transistor DT2 can operate to flow a driving current between the high potential power line VDD and the low potential power line VSS.

For example, the driving current flowing between the high potential power line VDD and the low potential power line VSS by the first driving transistor DT1 can flow to the low potential power line VSS through the light emitting element SP3_ED of the third sub-pixel, for example, through the first light emitting unit including the 1-3 light emitting layer 143 and through the second light emitting unit including the 2-3 light emitting layer 183.

The display device 100 according to the example embodiment of the present disclosure can include a plurality of auxiliary lines AE disposed between adjacent pixels.

For example, an auxiliary line AE can be included between the light emitting element SP3_ED of the third sub-pixel and the light emitting element SP2_ED of the second sub-pixel.

Accordingly, even though some of the driving current flowing between high potential power line VDD, the light emitting element SP3_ED of the third sub-pixel, and the low potential power line VSS flows in the direction toward the adjacent plurality of sub pixels, for example, the light emitting element SP2_ED of the second sub pixel, the flow of the driving current is changed by the auxiliary electrode AE to be induced to the low potential power line VSS.

In general, in the case of a single light emitting unit structure including one organic light emitting layer as an organic layer of a display device, there is a problem in that the luminous efficiency and power consumption are lowered compared to a multi-light emitting unit structure including a plurality of organic light emitting layers as an organic layer. To overcome this, when a multi-light emitting unit structure including a plurality of organic light emitting layers is applied as an organic layer, luminous efficiency and power consumption are improved, but there is a problem in that a leakage current is generated between a plurality of adjacent sub pixels.

Accordingly, in the display device 100 according to the example embodiment of the present disclosure, the auxiliary electrode AE including the first hole H1 is disposed in the sub pixel SP and the first charge generation layer 160 and the second charge generation layer 165 having high conductivity and the auxiliary electrode AE are electrically connected in the first hole H1. Therefore, the leakage current flowing between the plurality of adjacent sub pixels SP can be induced to the auxiliary electrode AE and the low potential power line VSS electrically connected to the auxiliary electrode AE through the first charge generation layer 160 and the second charge generation layer 165 in the first hole H1. Accordingly, the display device 100 according to the example embodiment of the present disclosure not only achieves high efficiency and low power consumption, but also blocks a leakage current between a plurality of adjacent sub pixels SP. In addition, it is possible to reduce process cost by improving the leakage current problem without an additional process using an exposure mask.

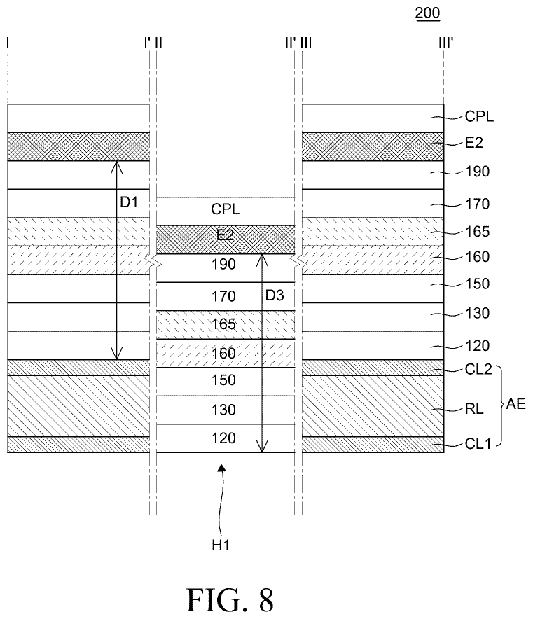

FIG. 8 is a schematic cross-sectional view of a display device according to another embodiment of the present disclosure. A display device 200 of FIG. 8 has the substantially same configuration as the display device 100 of FIGS. 1 to 7 except for the organic layer EL in an area overlapping the auxiliary electrode AE, so that a redundant description will be omitted or may be briefly provided.

Referring to FIG. 8, in the display device 200 according to another example embodiment of the present disclosure, the organic layer EL overlapping the auxiliary electrode AE can include a hole injection layer 120, a first hole transport layer 130, a first electron transport layer 150, a first charge generation layer 160, a second charge generation layer 165, a second hole transport layer 170, and a second electron transport layer 190.

In this case, a first hole H1 exposing the upper surface of the second planarization layer 115b can be included in at least a part of the auxiliary electrode AE. The first hole H1 can be formed by irradiating a laser after the auxiliary electrode AE is formed. For example, an auxiliary electrode AE is formed on the second planarization layer 115b. Subsequently, a first hole H1 is formed in at least a portion of the auxiliary electrode AE using a laser. Thereafter, the hole injection layer 120, the first hole transport layer 130, the first charge generation layer 160, the second charge generation layer 165, the second hole transport layer 170, and the second electron transport layer 190 can be formed. However, the order of forming the first hole H1 in at least a part of the auxiliary electrode AE may not be limited as long as it is before the first charge generation layer 160 is formed. For example, the auxiliary electrode AE can be formed, and then the hole injection layer 120, the first hole transport layer 130, and the first electron transport layer 150 can be formed, and then the first hole H1 can be formed using a laser. In this case, the auxiliary electrode AE can be in direct contact with the first charge generation layer 160 to be electrically connected.

In the display device 200 according to another example embodiment of the present disclosure, the thickness D1 of the organic layer EL disposed on the upper surface of the auxiliary electrode AE can be equal to the thickness D3 of the organic layer EL disposed in the first hole H1.

The organic layer EL disposed in the first hole H1 can include a hole injection layer 120, a first hole transport layer 130, a first electron transport layer 150, a first charge generation layer 160, a second charge generation layer 165, a second hole transport layer 170, and a second electron transport layer 190 in the same manner as an upper surface of the auxiliary electrode AE.

In the first hole H1 or on an upper surface of the second planarization layer 115b in the first hole H1, only the hole injection layer 120, the first hole transport layer 130, the first electron transport layer 150, the first charge generation layer 160, the second charge generation layer 165, the second hole transport layer 170, and the second electron transport layer 190 in the organic layer EL can be disposed, and the plurality of auxiliary electrodes AE can be in contact with the hole injection layer 120 and electrically connected to the first charge generation layer 160 and the second charge generation layer 165 through the hole injection layer 120. Accordingly, the auxiliary electrode AE can be electrically connected to the first charge generation layer 160 and the second charge generation layer 165 having high conductivity. Further, the low potential power line VSS electrically connected to the auxiliary electrode AE can also be electrically connected to the first charge generation layer 160 and the second charge generation layer 165.

In the display device 200 according to another example embodiment of the present disclosure, the auxiliary electrode AE including the first hole H1 is disposed in the sub pixel SP and the first charge generation layer 160 and the second charge generation layer 165 having high conductivity are electrically connected to the auxiliary electrode AE in the first hole H1. Therefore, the leakage current flowing between the plurality of adjacent sub pixels SP can be induced to the auxiliary electrode AE and the low potential power line VSS electrically connected to the auxiliary electrode AE through the first charge generation layer 160 and the second charge generation layer 165 in the first hole H1. Accordingly, the display device 200 according to another example embodiment of the present disclosure not only achieves high efficiency and low power consumption, but also blocks a leakage current between a plurality of adjacent sub pixels SP.

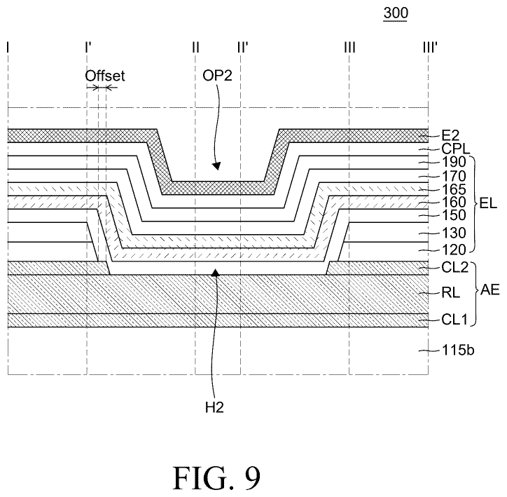

FIG. 9 is a schematic cross-sectional view of a display device according to still another example embodiment of the present disclosure. A display device 300 of FIG. 9 is substantially identical in configuration to the display device 100, 200 of FIGS. 1 to 8, except for a shape of an auxiliary electrode AE. Therefore, repeated descriptions of the identical components will be omitted or may be briefly provided.

In the display device 300 according to still another example embodiment of the present disclosure, the plurality of auxiliary electrodes AE is disposed on the second planarization layer 115b. The plurality of auxiliary electrodes AE can include a first transparent conductive layer CL1, a reflective layer RL on the first transparent conductive layer CL1, and a second transparent conductive layer CL2 on the reflective layer RL. For example, each of the first transparent conductive layer CL1 and the second transparent conductive layer CL2 can be made of a transparent conductive oxide such as ITO or IZO, and the reflective layer RL can be made of silver (Ag), aluminum (Al), gold (Au), molybdenum (Mo), tungsten (W), chromium (Cr), or an alloy thereof.

At least a part of the plurality of auxiliary electrodes AE can include a second hole H2 exposing a part of the upper surface of the reflective layer RL and a part of the side surface of the second transparent conductive layer CL2.

Further, the bank 116 on the top of the plurality of auxiliary electrodes AE can include a second opening OP2 overlapping the second hole H2 and exposing a part of the upper surface of the plurality of reflective layers RL. The organic layer EL can be disposed on the reflective layer RL exposed through the second opening OP2 of the bank 116.

The second hole H2 can be formed by irradiating a laser after the auxiliary electrode AE is formed. For example, the auxiliary electrode AE is formed on the second planarization layer 115b, and then the hole injection layer 120 and the first hole transport layer 130 are formed. Then, a second hole H2 is formed in a part of the auxiliary electrode, for example, the second transparent conductive layer CL2, the hole injection layer 120, and the first hole transport layer 130 using a laser. Next, the first electron transport layer 150, the first charge generation layer 160, the second charge generation layer 165, the second hole transport layer 170, and the second electron transport layer 190 can be formed.

In the display device 300 according to still another example embodiment of the present disclosure, the second hole H2 is formed by irradiating at least a part of the auxiliary electrode AE with laser beams. Therefore, the upper surface of the reflective layer RL and the side surface of the second transparent conductive layer CL2 can be exposed in the second hole H2. Accordingly, when the organic layer EL is disposed on the upper surface of the auxiliary electrode AE, the contact area between the auxiliary electrode AE and the organic layer EL is increased so that the contact resistance can be improved.

As the second hole H2 is formed in a part of the second transparent conductive layer CL2 using a laser, the side surface of the second transparent conductive layer CL2 can have a gentle taper shape. In addition, as the second hole H2 is formed in the second transparent conductive layer CL2 using a laser, an offset can be formed between the second transparent conductive layer CL2 and the hole injection layer 120 and the first hole transport layer 130 disposed above the second transparent conductive layer CL2.

The organic layer EL overlapping the plurality of auxiliary electrodes AE can include a hole injection layer 120, a first hole transport layer 130, a first electron transport layer 150, a first charge generation layer 160, a second charge generation layer 165, a second hole transport layer 170, and a second electron transport layer 190.

In the second hole H2 or on the reflective layer RL in the second hole H2, only the first electron transport layer 150, the first charge generation layer 160, the second charge generation layer 165, the second hole transport layer 170, and the second electron transport layer 190 among the organic layer EL can be disposed.

Referring to FIG. 9, the organic layer EL disposed on the upper surface of the auxiliary electrode AE can further include a hole injection layer 120 and a first hole transport layer 130 than the organic layer EL disposed in the second hole H2. Accordingly, the thickness D1 of the organic layer EL disposed on the upper surface of the auxiliary electrode AE can be greater than the thickness D2 of the organic layer EL disposed in the second hole H2.

In the second hole H2, the plurality of auxiliary electrodes AE is in contact with the first electron transport layer 150. In this case, since the upper surface of the reflective layer RL and the side surface of the second transparent conductive layer CL2 are exposed in the second hole H2, a contact area between the organic layer EL and the auxiliary electrode AE, for example, the first electron transport layer 150 which are in direct contact can increase. The auxiliary electrode AE can be electrically connected to the first charge generation layer 160 and the second charge generation layer 165 through the first electron transport layer 150. Accordingly, the auxiliary electrode AE can be electrically connected to the first charge generation layer 160 and the second charge generation layer 165 having high conductivity. Further, the low potential power line VSS electrically connected to the auxiliary electrode AE can also be electrically connected to the first charge generation layer 160 and the second charge generation layer 165.

In the display device 300 according to still another example embodiment of the present disclosure, the auxiliary electrode AE is disposed in the sub pixel SP and a second hole H2 is formed to expose a part of the auxiliary electrode AE, for example, an upper surface of the reflective layer RL and a part of a side surface of the second transparent conductive layer CL2. The first charge generation layer 160 and the second charge generation layer 165 having high conductivity are electrically connected to the auxiliary electrode AE in the second hole H2. Therefore, the leakage current flowing between the plurality of adjacent sub pixels SP can be induced to the auxiliary electrode AE and the low potential power line VSS electrically connected to the auxiliary electrode AE through the first charge generation layer 160 and the second charge generation layer 165 in the second hole H2. Further, as the contact area of the organic layer, e.g., the first electron transport layer 150 which electrically connects the auxiliary electrode AE to the first charge generation layer 160 and the second charge generation layer 165 increases, the contact resistance can be improved. Accordingly, the display device 300 according to still another example embodiment of the present disclosure not only achieves high efficiency and low power consumption, but also blocks a leakage current between a plurality of adjacent sub pixels SP.

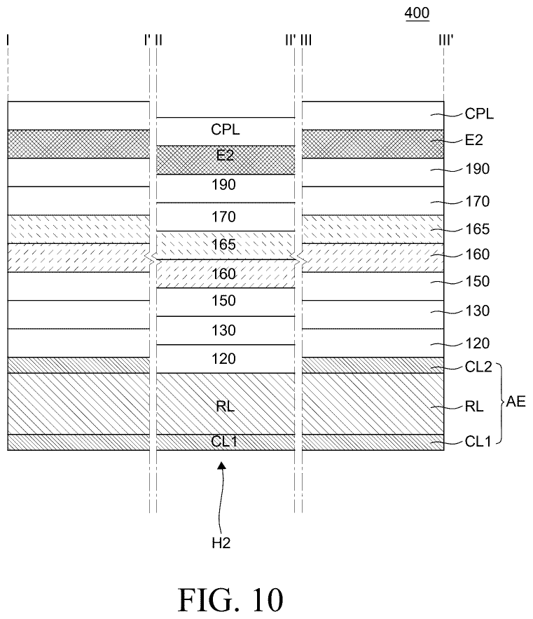

FIG. 10 is a schematic cross-sectional view of a display device according to still another example embodiment of the present disclosure. A display device 400 of FIG. 10 has the substantially same configuration as the display device 300 of FIG. 9 except for an organic layer EL in an area overlapping the auxiliary electrode AE, so that a redundant description will be omitted or may be briefly provided.

Referring to FIG. 10, in the display device 400 according to still another example embodiment of the present disclosure, the organic layer EL overlapping the auxiliary electrode AE can include a hole injection layer 120, a first hole transport layer 130, a first electron transport layer 150, a first charge generation layer 160, a second charge generation layer 165, a second hole transport layer 170, and a second electron transport layer 190.

In this case, the plurality of auxiliary electrodes AE can include a first transparent conductive layer CL1, a reflective layer RL on the first transparent conductive layer CL1, and a second transparent conductive layer CL2 on the reflective layer RL. For example, each of the first transparent conductive layer CL1 and the second transparent conductive layer CL2 can be made of a transparent conductive oxide such as ITO or IZO, and the reflective layer RL can be made of silver (Ag), aluminum (Al), gold (Au), molybdenum (Mo), tungsten (W), chromium (Cr), or an alloy thereof.

The plurality of auxiliary electrodes AE can include a second hole H2 exposing a part of an upper surface of the reflective layer RL and a part of a side surface of the second transparent conductive layer CL2.

Further, the bank 116 on the top of the plurality of auxiliary electrodes AE overlaps the second hole H2 and can include a second opening OP2 exposing a part of the upper surface of the plurality of reflective layers RL. The organic layer EL can be disposed on the reflective layer RL exposed through the second opening OP2 of the bank 116.

The second hole H2 can be formed by irradiating a laser after the auxiliary electrode AE is formed. For example, an auxiliary electrode AE is formed on the second planarization layer 115b. Subsequently, a second hole H2 is formed in a part of the auxiliary electrode, for example, the second transparent conductive layer CL2, using a laser. Thereafter, the hole injection layer 120, the first hole transport layer 130, the first charge generation layer 160, the second charge generation layer 165, the second hole transport layer 170, and the second electron transport layer 190 can be formed. However, the order of forming the second hole H2 in at least a part of the auxiliary electrode AE may not be limited as long as it is before the first charge generation layer 160 is formed. For example, the auxiliary electrode AE can be formed, and then the hole injection layer 120, the first hole transport layer 130, and the first electron transport layer 150 can be formed, and then the second hole H2 can be formed using a laser. In this case, the auxiliary electrode AE can be in direct contact with the first charge generation layer 160 to be electrically connected.

In the display device 400 according to still another example embodiment of the present disclosure, the second hole H2 is formed by irradiating a part of the auxiliary electrode AE with laser beams. Thus, the upper surface of the reflective layer RL and the side surface of the second transparent conductive layer CL2 can be exposed through the second hole H2. Accordingly, when the organic layer EL is disposed on the upper surface of the auxiliary electrode AE, the contact area between the auxiliary electrode AE and the organic layer EL is increased so that the contact resistance can be improved.

The organic layer EL disposed in the second hole H2 can include a hole injection layer 120, a first hole transport layer 130, a first electron transport layer 150, a first charge generation layer 160, a second charge generation layer 165, a second hole transport layer 170, and a second electron transport layer 190 in the same manner as an upper surface of the auxiliary electrode AE.

In the second hole H2 or on the reflective layer RL in the second hole H2, only the hole injection layer 120, the first hole transport layer 130, the first electron transport layer 150, the first charge generation layer 160, the second charge generation layer 165, the second hole transport layer 170, and the second electron transport layer 190 in the organic layer EL can be disposed, and the plurality of auxiliary electrodes AE is in contact with the hole injection layer 120. In this case, since the upper surface of the reflective layer RL and the side surface of the second transparent conductive layer CL2 are exposed in the second hole H2, a contact area between the organic layer EL and the auxiliary electrode AE, for example, the hole injection layer 120 which is in direct contact, can increase. The auxiliary electrode AE can be electrically connected to the first charge generation layer 160 and the second charge generation layer 165 through the hole injection layer 120. Accordingly, the auxiliary electrode AE can be electrically connected to the first charge generation layer 160 and the second charge generation layer 165 having high conductivity. Further, the low potential power line VSS electrically connected to the auxiliary electrode AE can also be electrically connected to the first charge generation layer 160 and the second charge generation layer 165.

In the display device 400 according to still another example embodiment of the present disclosure, the auxiliary electrode AE is disposed in the sub pixel SP and a second hole H2 is formed to expose a part of the auxiliary electrode AE, for example, an upper surface of the reflective layer RL and a part of a side surface of the second transparent conductive layer CL2. The first charge generation layer 160 and the second charge generation layer 165 having high conductivity are electrically connected to the auxiliary electrode AE in the second hole H2. Therefore, the leakage current flowing between the plurality of adjacent sub pixels SP can be induced to the auxiliary electrode AE and the low potential power line VSS electrically connected to the auxiliary electrode AE through the first charge generation layer 160 and the second charge generation layer 165 in the second hole H2. Further, as the contact area of the organic layer, e.g., the hole injection layer 120 which electrically connects the auxiliary electrode AE to the first charge generation layer 160 and the second charge generation layer 165 increases, the contact resistance can be improved. Accordingly, the display device 400 according to still another example embodiment of the present disclosure not only achieves high efficiency and low power consumption, but also blocks a leakage current between a plurality of adjacent sub pixels SP.

The example embodiments of the present disclosure can also be described as follows:

According to an aspect of the present disclosure, a display device includes a substrate, a planarization layer disposed on the substrate, a plurality of first electrodes disposed on the planarization layer, a plurality of auxiliary electrodes disposed on the planarization layer so as to be spaced apart from the plurality of first electrodes, an organic layer on the plurality of first electrodes and the plurality of auxiliary electrodes, and a second electrode disposed on the organic layer. A part of an upper surface and a side surface of the plurality of auxiliary electrodes are in contact with the organic layer.

The display device can further include a plurality of power lines disposed between the substrate and the planarization layer. The plurality of auxiliary electrodes can be electrically connected to the plurality of power lines, respectively.

According to another feature of the present disclosure, at least a part of the plurality of auxiliary electrodes can include a first hole exposing an upper surface of the planarization layer.

The display device can further include a bank disposed to cover ends of the plurality of first electrodes. The bank can include a first opening which overlaps the first hole and exposes a part of an upper surface and a part of a side surface of the plurality of auxiliary electrodes.

The thickness of the organic layer disposed on the upper surfaces of the plurality of auxiliary electrodes can be greater than or equal to the thickness of the organic layer disposed in the first hole.

According to another feature of the present disclosure, the organic layer can include a first light emitting unit including a hole injection layer, a first hole transport layer, and a first electron transport layer, a charge generation layer on the first light emitting unit, and a second light emitting unit disposed on the charge generation layer and including a second hole transport layer and a second electron transport layer, in the first hole, only the first electron transport layer, the charge generation layer, the second hole transport layer, and the second electron transport layer among the organic layer are disposed, and in the first hole, the plurality of auxiliary electrodes can be in contact with the first electron transport layer and electrically connected to the charge generation layer through the first electron transport layer.

According to another feature of the present disclosure, the organic layer can include a first light emitting unit including a hole injection layer, a first hole transport layer, and a first electron transport layer, a charge generation layer on the first light emitting unit, and a second light emitting unit disposed on the charge generation layer and including a second hole transport layer and a second electron transport layer, in the first hole, only a hole injection layer, a first hole transport layer, a first electron transport layer, a charge generation layer, a second hole transport layer, and a second electron transport layer among the organic layer are disposed, and in the first hole, the plurality of auxiliary electrodes is in contact with the hole injection layer and can be electrically connected to the charge generation layer through the hole injection layer.

The plurality of auxiliary electrodes can include a first transparent conductive layer, a reflective layer on the first transparent conductive layer, and a second transparent conductive layer on the reflective layer, and at least a part of the plurality of auxiliary electrodes can include a second hole exposing a part of an upper surface of the reflective layer.

The display device can further include a bank configured to cover ends of the plurality of first electrodes and define an emission area, the bank including a second opening overlapping the second hole and exposing a portion of an upper surface of the plurality of reflective layers.

According to another feature of the present disclosure, the organic layer can include a first light emitting unit including a hole injection layer, a first hole transport layer, and a first electron transport layer, a charge generation layer on the first light emitting unit, and a second light emitting unit disposed on the charge generation layer and including a second hole transport layer and a second electron transport layer, in the second hole, only the first electron transport layer, the charge generation layer, the second hole transport layer, and the second electron transport layer among the organic layer are disposed, and in the second hole, the plurality of auxiliary electrodes can be in contact with the first electron transport layer and electrically connected to the charge generation layer through the first electron transport layer.

According to another feature of the present disclosure, the organic layer can include a first light emitting unit including a hole injection layer, a first hole transport layer, and a first electron transport layer, a charge generation layer on the first light emitting unit, and a second light emitting unit disposed on the charge generation layer and including a second hole transport layer and a second electron transport layer, in the second hole, only a hole injection layer, a first hole transport layer, a first electron transport layer, a charge generation layer, a second hole transport layer, and a second electron transport layer among the organic layer are disposed, and in the second hole, the plurality of auxiliary electrodes can be in contact with the hole injection layer and electrically connected to the charge generation layer through the hole injection layer.

A display device according to another example embodiment of the present disclosure includes a substrate on which a plurality of sub-pixels is defined; a plurality of transistors disposed on the substrate; a plurality of power lines disposed on the substrate; a planarization layer disposed on the plurality of transistors and the plurality of power lines; a plurality of first electrodes disposed in each of the plurality of sub-pixels on the planarization layer and electrically connected to the plurality of transistors; a plurality of auxiliary electrodes disposed between the plurality of first electrodes on the planarization layer and electrically connected to the plurality of power lines; an organic layer disposed on the plurality of first electrodes and the plurality of auxiliary electrodes; and a second electrode disposed on the organic layer, a part of an upper surface and a side surface of the plurality of auxiliary electrodes in contact with the organic layer.

According to another feature of the present disclosure, at least a part of the plurality of auxiliary electrodes can include a first hole exposing a part of the upper surface of the planarization layer.

According to another feature of the present disclosure, the thickness of the organic layer disposed on the plurality of auxiliary electrode can be greater than or equal to the thickness of the organic layer disposed on the upper surface of the planarization layer in the first hole.

The organic layer disposed on the plurality of auxiliary electrode can include a hole injection layer, a first hole transport layer, a first electron transport layer, a charge generation layer, a second hole transport layer, and a second electron transport layer, and the organic layer disposed on the upper surface of the planarization layer in the first hole can include a first electron transport layer, a charge generation layer, a second hole transport layer, and a second electron transport layer.

The organic layer disposed on the plurality of auxiliary electrode can include a hole injection layer, a first hole transport layer, a first electron transport layer, a charge generation layer, a second hole transport layer, and a second electron transport layer, and the organic layer disposed on the upper surface of the planarization layer in the first hole can include a hole injection layer, a first hole transport layer, a first electron transport layer, a charge generation layer, a second hole transport layer, and a second electron transport layer.

According to another feature of the present disclosure, the plurality of auxiliary electrodes can include a first transparent conductive layer, a reflective layer on the first transparent conductive layer, and a second transparent conductive layer on the reflective layer, and at least a part of the plurality of auxiliary electrodes can include a second hole exposing a part of the reflective layer.

According to another feature of the present disclosure, the thickness of the organic layer disposed on the first transparent conductive layer can be greater than or equal to the thickness of the organic layer disposed on the reflective layer in the second hole.

The organic layer disposed on the first transparent conductive layer can include a hole injection layer, a first hole transport layer, a first electron transport layer, a charge generation layer, a second hole transport layer, and a second electron transport layer, and the organic layer disposed on the reflective layer in the second hole can include a first electron transport layer, a charge generation layer, a second hole transport layer, and a second electron transport layer.

The organic layer disposed on the first transparent conductive layer can include a hole injection layer, a first hole transport layer, a first electron transport layer, a charge generation layer, a second hole transport layer, and a second electron transport layer, and the organic layer disposed on the reflective layer in the second hole can include a hole injection layer, a first hole transport layer, a first electron transport layer, a charge generation layer, a second hole transport layer, and a second electron transport layer.

Although the example embodiments of the present disclosure have been described in detail with reference to the accompanying drawings, the present disclosure is not limited thereto and can be embodied in various forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

What is claimed is:

1. A display device comprising:
a substrate;
a planarization layer disposed on the substrate;
a plurality of first electrodes disposed on the planarization layer;
a plurality of auxiliary electrodes disposed on the planarization layer so as to be spaced apart from the plurality of first electrodes;
an organic layer on the plurality of first electrodes and the plurality of auxiliary electrodes; and
a second electrode disposed on the organic layer,
wherein a part of an upper surface and a side surface of the plurality of auxiliary electrodes is in contact with the organic layer.

2. The display device according to claim 1, further comprising:
a plurality of power lines disposed between the substrate and the planarization layer,
wherein the plurality of auxiliary electrodes is electrically connected to the plurality of power lines, respectively.

3. The display device according to claim 2, wherein at least a part of the plurality of auxiliary electrodes includes a first hole exposing an upper surface of the planarization layer.

4. The display device according to claim 3, further comprising:
a bank disposed to cover ends of the plurality of first electrodes,
wherein the bank includes a first opening overlapping the first hole and exposing a part of the upper surface and a part of the side surface of the plurality of auxiliary electrodes.

5. The display device according to claim 4, wherein a thickness of the organic layer disposed on the upper surfaces of the plurality of auxiliary electrodes is equal to or greater than a thickness of the organic layer disposed in the first hole.

6. The display device according to claim 4, wherein the organic layer includes:
a first light emitting unit including a hole injection layer, a first hole transport layer, and a first electron transport layer;
a charge generation layer on the first light emitting unit; and
a second light emitting unit disposed on the charge generation layer and including a second hole transport layer and a second electron transport layer,
in the first hole, only the first electron transport layer, the charge generation layer, the second hole transport layer, and the second electron transport layer among the organic layer are disposed, and
in the first hole, the plurality of auxiliary electrodes is in contact with the first electron transport layer and is electrically connected to the charge generation layer through the first electron transport layer.

7. The display device according to claim 4, wherein the organic layer includes:
a first light emitting unit including a hole injection layer, a first hole transport layer, and a first electron transport layer;
a charge generation layer on the first light emitting unit; and
a second light emitting unit disposed on the charge generation layer and including a second hole transport layer and a second electron transport layer, and
in the first hole, only the hole injection layer, the first hole transport layer, the first electron transport layer, the charge generation layer, the second hole transport layer, and the second electron transport layer among the organic layer are disposed, and
in the first hole, the plurality of auxiliary electrodes is in contact with the hole injection layer and is electrically connected to the charge generation layer through the hole injection layer.

8. The display device according to claim 2, wherein the plurality of auxiliary electrodes includes a first transparent conductive layer, a reflective layer on the first transparent conductive layer, and a second transparent conductive layer on the reflective layer, and
at least a part of the plurality of auxiliary electrodes includes a second hole exposing a part of an upper surface of the reflective layer.

9. The display device according to claim 8, further comprising:
a bank configured to cover ends of the plurality of first electrodes and define an emission area,
wherein the bank includes a second opening configured to overlap the second hole, and expose a part of an upper surface of the reflective layer.

10. The display device according to claim 9, wherein the organic layer includes:
a first light emitting unit including a hole injection layer, a first hole transport layer, and a first electron transport layer;
a charge generation layer on the first light emitting unit; and
a second light emitting unit disposed on the charge generation layer and including a second hole transport layer and a second electron transport layer,
in the second hole, only the first electron transport layer, the charge generation layer, the second hole transport layer, and the second electron transport layer among the organic layer are disposed, and
in the second hole, the plurality of auxiliary electrodes is in contact with the first electron transport layer and is electrically connected to the charge generation layer through the first electron transport layer.

11. The display device according to claim 9, wherein the organic layer includes:
a first light emitting unit including a hole injection layer, a first hole transport layer, and a first electron transport layer;
a charge generation layer on the first light emitting unit; and
a second light emitting unit disposed on the charge generation layer and including a second hole transport layer and a second electron transport layer, and
in the second hole, only the hole injection layer, the first hole transport layer, the first electron transport layer, the charge generation layer, the second hole transport layer, and the second electron transport layer among the organic layer are disposed, and
in the second hole, the plurality of auxiliary electrodes is in contact with the hole injection layer and is electrically connected to the charge generation layer through the hole injection layer.

12. A display device comprising:
a substrate on which a plurality of sub pixels is defined;
a plurality of transistors disposed on the substrate;
a plurality of power lines disposed on the substrate;
a planarization layer disposed on the plurality of transistors and the plurality of power lines;
a plurality of first electrodes disposed on the planarization layer in each of the plurality of sub pixels and electrically connected to the plurality of transistors;
a plurality of auxiliary electrodes disposed between the plurality of first electrodes on the planarization layer and electrically connected to the plurality of power lines;
an organic layer disposed on the plurality of first electrodes and the plurality of auxiliary electrodes; and
a second electrode disposed on the organic layer,
wherein a part of an upper surface and a side surface of the plurality of auxiliary electrodes is in contact with the organic layer.

13. The display device according to claim 12, wherein at least a part of the plurality of auxiliary electrodes includes a first hole which exposes a part of an upper surface of the planarization layer.

14. The display device according to claim 13, wherein a thickness of the organic layer disposed on the plurality of auxiliary electrode is greater than or equal to a thickness of the organic layer disposed on the upper surface of the planarization layer in the first hole.

15. The display device according to claim 14, wherein the organic layer disposed on the plurality of auxiliary electrode includes a hole injection layer, a first hole transport layer, a first electron transport layer, a charge generation layer, a second hole transport layer, and a second electron transport layer, and
the organic layer disposed on an upper surface of the planarization layer in the first hole includes the first electron transport layer, the charge generation layer, the second hole transport layer, and the second electron transport layer.

16. The display device according to claim 14, wherein the organic layer disposed on the plurality of auxiliary electrode includes a hole injection layer, a first hole transport layer, a first electron transport layer, a charge generation layer, a second hole transport layer, and a second electron transport layer, and
the organic layer disposed on an upper surface of the planarization layer in the first hole includes the hole injection layer, the first hole transport layer, the first electron transport layer, the charge generation layer, the second hole transport layer, and the second electron transport layer.

17. The display device according to claim 12, wherein the plurality of auxiliary electrodes includes a first transparent conductive layer, a reflective layer on the first transparent conductive layer, and a second transparent conductive layer on the reflective layer, and
at least a part of the plurality of auxiliary electrodes includes a second hole exposing a part of the reflective layer.

18. The display device of claim 17, wherein a thickness of the organic layer disposed on the first transparent conductive layer is greater than or equal to a thickness of the organic layer disposed on the reflective layer in the second hole.

19. The display device according to claim 17, wherein the organic layer disposed on the first transparent conductive layer includes a hole injection layer, a first hole transport layer, a first electron transport layer, a charge generation layer, a second hole transport layer, and a second electron transport layer, and
the organic layer disposed on the reflective layer in the second hole includes the first electron transport layer, the charge generation layer, the second hole transport layer, and the second electron transport layer.

20. The display device according to claim 17, wherein the organic layer disposed on the first transparent conductive layer includes a hole injection layer, a first hole transport layer, a first electron transport layer, a charge generation layer, a second hole transport layer, and a second electron transport layer, and
the organic layer disposed on the reflective layer in the second hole includes the hole injection layer, the first hole transport layer, the first electron transport layer, the charge generation layer, the second hole transport layer, and the second electron transport layer.
